(19) United States
(12) Patent Application Publication
(10) Pub. No.: US 2024/0224757 A1
(43) Pub. Date: Jul. 4, 2024

(54) DISPLAY APPARATUS

(71) Applicant: LG Display Co., Ltd., Seoul (KR)

(72) Inventors: SeoHyun NAM, Paju-si, (KR); SeHong PARK, Paju-si (KR); Wonrae KIM, Paju-si, (KR); Hyemin PARK, Paju-si (KR); Sejong SEONG, Paju-si (KR)

(73) Assignee: LG Display Co., Ltd., Seoul (KR)

(21) Appl. No.: 18/530,688

(22) Filed: Dec. 6, 2023

(30) Foreign Application Priority Data
Dec. 30, 2022 (KR) 10-2022-0190870

(51) Int. Cl. H10K 59/80; H10K 59/122; H10K 59/35

(52) U.S. Cl. CPC H10K 59/879; H10K 59/122; H10K 59/351; H10K 59/873; H10K 59/878; H10K 59/38

(57) ABSTRACT

A display apparatus may include a substrate, subpixels, a concave pattern portion, and a reflective portion on the pattern portion. Subpixels include a light emission area including a light emitting layer and a bank in a non-light emission area. A total amount of light emitted from the light emitting layer and output to the substrate satisfies

$${η}_{total} = A {\int }_{0}^{{sin}^{- 1} ( \frac{{n}_{b}}{{n}_{OLED} \cdot \sqrt{1 + {( \frac{h}{v} )}^{2}}} )} {I}_{OLED} ( θ ) d θ + B .$$

A is a light conversion constant, n_{OLED} is a refractive index of the light emitting layer, n_{b} is a refractive index of the bank, V is a vertical length from an upper surface of the light emitting layer to an ending point of the bank, h is a horizontal length from an end of the light emission area to the ending point of the bank, I_{OLED}(θ) is the amount of light emitted from the inside of the light emitting layer, and B is a total output amount of light without a reflective portion.

### CROSS-REFERENCE TO RELATED APPLICATIONS

This application claims the benefit of and priority to Korean Patent Application No. 10-2022-0190870 filed on Dec. 30, 2022, the entirety of which is incorporated herein by reference for all purposes.

### BACKGROUND

### 1. Technical Field

The present disclosure relates to an apparatus and particularly to, for example, without limitation, a display apparatus for displaying an image.

### 2. Discussion of the Related Art

Since an organic light emitting display apparatus has a high response speed and low power consumption and self-emits light without requiring a separate light source unlike a liquid crystal display apparatus, there is typically no problem with its viewing angle, and thus the organic light emitting display apparatus has received attention as a next-generation flat panel display apparatus.

Such a display apparatus displays an image through light emission of a light emitting element layer that includes a light emitting layer interposed between two electrodes.

Meanwhile, light extraction efficiency of the display apparatus is reduced as some of light emitted from the light emitting element layer is not emitted to the outside due to total reflection at or on the interface between the light emitting element layer and an electrode and/or between a substrate and an air layer.

The description provided in the discussion of the related art section should not be assumed to be prior art merely because it is mentioned in or associated with that section. The discussion of the related art section may include information that describes one or more aspects of the subject technology, and the description in this section does not limit the invention.

### SUMMARY

The inventors of the present disclosure have recognized the problems and disadvantages of the related art, have performed extensive research and experiments, and have developed a new invention. Accordingly, one or more aspects of the present disclosure are directed to a display apparatus that substantially obviate one or more of the problems due to limitations and disadvantages of the related art.

In one or more aspects, an object of the present disclosure is to provide a display apparatus that may improve light extraction efficiency of light emitted from a light emitting element layer.

In one or more aspects, another object of the present disclosure is to provide a display apparatus that may further improve light extraction efficiency through light extraction from a non-light emission area.

In one or more aspects, yet another object of the present disclosure is to provide a display apparatus that may reduce overall power consumption through light extraction from a non-light emission area.

In addition to the objects of the present disclosure as mentioned above, additional objects, aspects, features and advantages of the present disclosure are set forth in the present disclosure and will also be apparent from the present disclosure or may be learned by practice of the inventive concepts provided herein. Other aspects, features and advantages of the present disclosure may be realized and attained by the descriptions provided in the present disclosure, including the claims and the drawings.

In accordance with one or more aspects of the present disclosure, the above and other objects and advantages can be accomplished by the provision of a display apparatus comprising a substrate, a plurality of pixels having a plurality of subpixels, a pattern portion disposed on the substrate and formed to be concave between the plurality of subpixels, and a reflective portion disposed to be inclined on the pattern portion. The plurality of subpixels may include a light emission area and a non-light emission area. The light emission area may include a light emitting layer. The non-light emission area may include a bank and may be adjacent to the light emission area. A total output amount of light emitted from the light emitting layer and output to the substrate is provided to satisfy

$${η}_{total} = A {\int }_{0}^{{sin}^{- 1} ( \frac{{n}_{b}}{{n}_{OLED} \cdot \sqrt{1 + {( \frac{h}{v} )}^{2}}} )} {I}_{OLED} ( θ ) d θ + B ,$$

where ηₜₒₜₐₗ is the total output amount of light emitted from the light emitting layer and output to the substrate, A is a light conversion constant, n_{OLED} is a refractive index of the light emitting layer, n_{b} is a refractive index of the bank, V is a vertical length from an upper surface of the light emitting layer to a point at which the bank ends, h is a horizontal length from an end of the light emission area to the point at which the bank ends, I_{OLED}(θ) is the amount of light emitted from the inside of the light emitting layer, and B is a total output amount of light when there is no reflective portion.

In accordance with one or more aspects of the present disclosure, the above and other objects and advantages can be accomplished by the provision of a display apparatus comprising a substrate, a plurality of pixels having a plurality of subpixels, a pattern portion disposed on the substrate and formed to be concave between the plurality of subpixels, and a reflective portion formed to be concave on the pattern portion. The plurality of subpixels may include a light emission area and a non-light emission area. The light emission area may include a light emitting layer. The non-light emission area may be adjacent to the light emission area. A depth of the reflective portion disposed in the non-light emission area may be proportional to a total output amount of light emitted from the light emitting layer and output to the substrate.

It is to be understood that both the foregoing description and the following description of the present disclosure are exemplary and explanatory, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles of the disclosure. In the drawings:

FIG. 1 is a schematic plan view illustrating a display apparatus according to an example embodiment of the present disclosure;

FIG. 2 is an example of a schematic cross-sectional view taken along line I-I′ shown in FIG. 1;

FIG. 3 is an example of an enlarged view illustrating a portion F of FIG. 2;

FIG. 4 is a graph illustrating an incident angle and a reflective coefficient at or on an interface of a light emitting layer of a display apparatus according to an example embodiment of the present disclosure;

FIGS. 5A and 5B are schematic views illustrating a depth of a reflective portion and a refractive angle of light incident on a bank from a light emitting layer of a display apparatus according to an example embodiment of the present disclosure; and

FIG. 6 is a graph illustrating the total output amount of light based on a depth of a reflective portion of a display apparatus according to an example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements, one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. The word “exemplary” is used to mean serving as an example or illustration. Embodiments are example embodiments. Aspects are example aspects. “Embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

In describing a positional relationship, where the positional relationship between two elements (e.g., layers, films, regions, components, sections, or the like) is described, for example, using “on,” “upon,” “on top of,” “over,” “under,” “above,” “below,” “beneath,” “near,” “close to,” “adjacent to,” “beside,” “next to,” “at or on a side of” or the like, one or more other elements may be located between the two elements unless a more limiting term, such as “immediate(ly),” “direct(ly),” or “close(ly),” is used. For example, when an element is described as being positioned “on,” “on a top of,” “upon,” “on top of,” “over,” “under,” “above,” “below,” “beneath,” “near,” “close to,” “adjacent to,” “beside,” “next to,” or “at or on a side of” another element, this description should be construed as including a case in which the elements contact each other directly as well as a case in which one or more additional elements are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

Spatially relative terms, such as “below,” “beneath,” “lower,” “on,” “above,” “upper” and the like, can be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, can include all directions of “above” and “below.” Likewise, an exemplary term “above” or “on” can include both directions of “above” and “below.”

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, regions, components, sections, or the like), these elements should not be limited by these terms, for example, to any particular order, precedence, or number of elements. These terms are used only to distinguish one element from another. For example, a first element could be a second element, and, similarly, a second element could be a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, or the like) is “connected,” “coupled,” “attached,” “adhered,” or the like to another element, the element can not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phase that an element (e.g., layer, film, region, component, section, or the like) is “provided in,” “disposed in,” or the like in another element may be understood as that at least a portion of the element is provided in, disposed in, or the like in another element, or that the entirety of the element is provided in, disposed in, or the like in another element. The phrase “through” may be understood to be at least partially through or entirely through. The phase that an element (e.g., layer, film, region, component, section, or the like) “contacts,” “overlaps,” or the like with another element may be understood as that at least a portion of the element contacts, overlaps, or the like with a least a portion of another element, that the entirety of the element contacts, overlaps, or the like with a least a portion of another element, or that at least a portion of the element contacts, overlaps, or the like with the entirety of another element.

The terms such as a “line” or “direction” should not be interpreted only based on a geometrical relationship in which the respective lines or directions are parallel or perpendicular to each other, and may be meant as lines or directions having wider directivities within the range within which the components of the present disclosure can operate functionally. For example, the terms “first direction,” “second direction,” and the like, such as the terms “first direction,” “second direction,” “vertical direction,” “horizontal direction,” “X-axis direction,” “Y-axis direction,” and “Z-axis direction,” should not be interpreted only based on a geometrical relationship in which the respective directions are parallel or perpendicular to each other, and may be meant as directions having wider directivities within the range within which the components of the present disclosure can operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, section, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

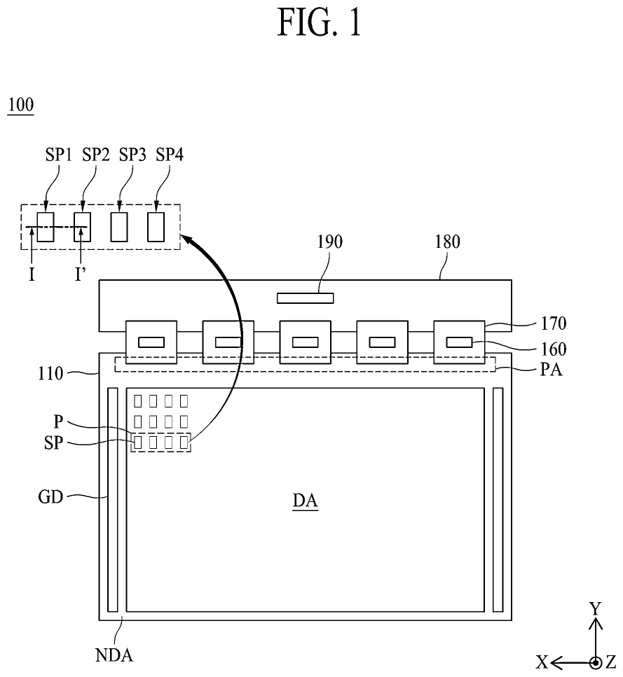

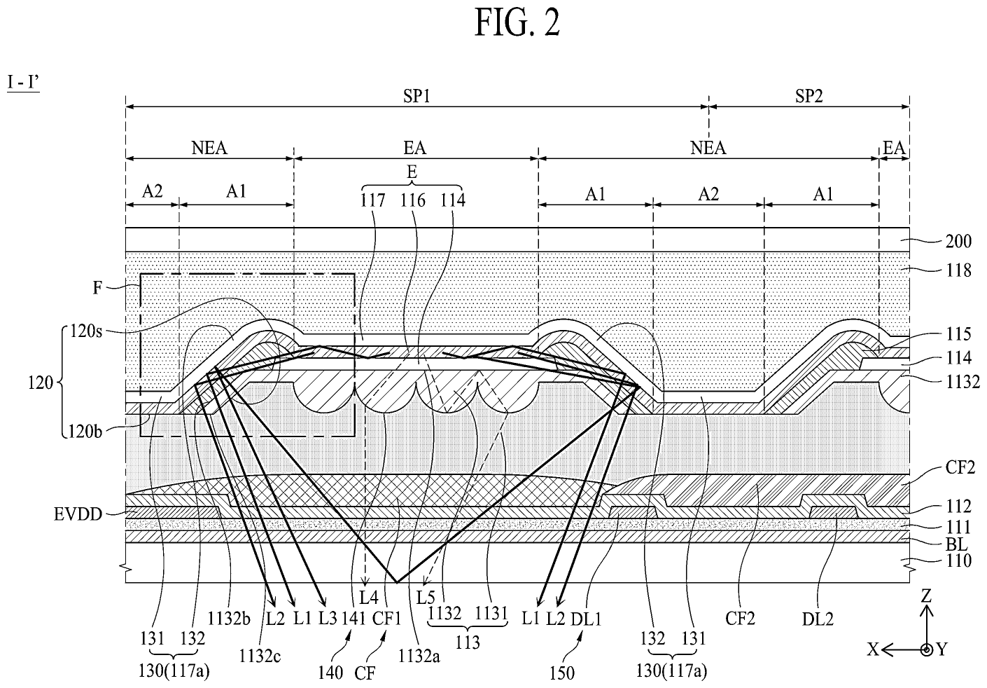

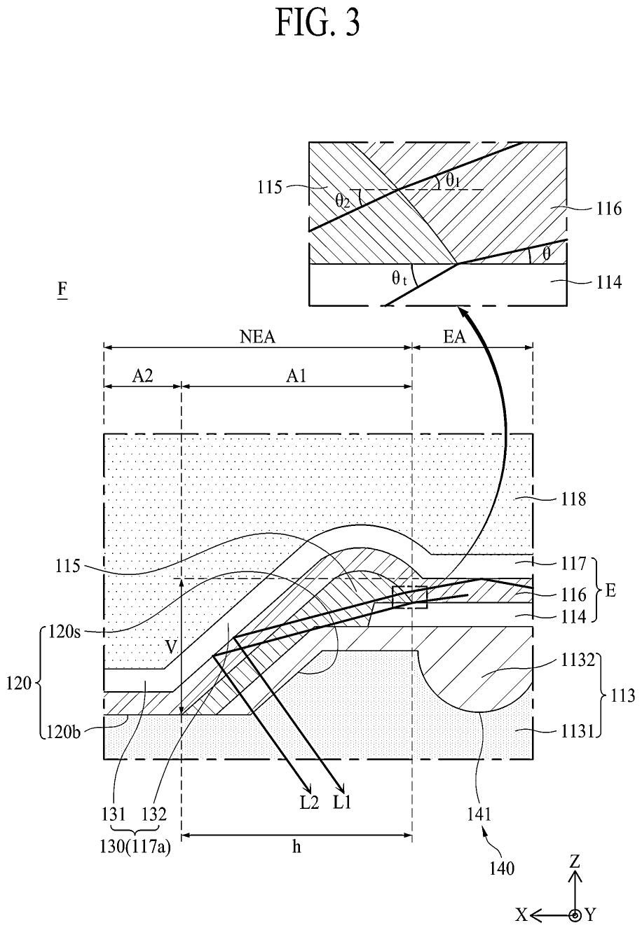

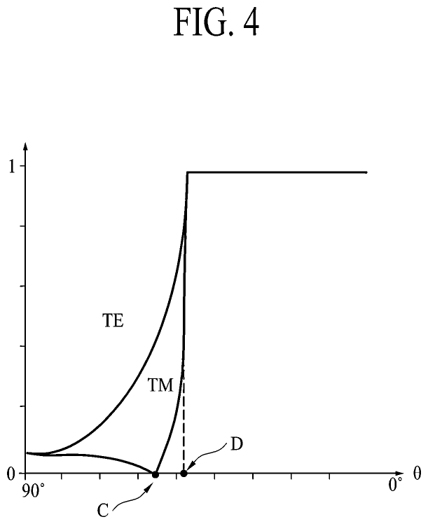

FIG. 1 is a schematic plan view illustrating a display apparatus according to an example embodiment of the present disclosure, FIG. 2 is an example of a schematic cross-sectional view taken along line I-I′ shown in FIG. 1, FIG. 3 is an example of an enlarged view illustrating a portion F of FIG. 2, and FIG. 4 is a graph illustrating an incident angle and a reflective coefficient at or on an interface of a light emitting layer of a display apparatus according to an example embodiment of the present disclosure.

Referring to FIGS. 1 to 4, a display apparatus 100 according to an example embodiment of the present disclosure includes a substrate 110, a plurality of pixels P having a plurality of subpixels SP, a pattern portion 120 disposed on the substrate 110 and formed to be concave between (or in each of) the plurality of subpixels SP, and a reflective portion 130 disposed to be inclined on the pattern portion 120.

The plurality of subpixels SP (or each of the plurality of subpixels SP) may include a light emission area EA including a light emitting layer 116 and a bank 115 in a non-light emission area NEA adjacent to the light emission area EA. In this case, the total output amount ηₜₒₜₐₗ of light emitted from the light emitting layer 116 and output to the substrate 110 (or the lower surface of the substrate 110) may be provided to satisfy

$${η}_{total} = A {\int }_{0}^{{sin}^{- 1} ( \frac{{n}_{b}}{{n}_{OLED} \cdot \sqrt{1 + {( \frac{h}{v} )}^{2}}} )} {I}_{OLED} ( θ ) d θ + B .$$

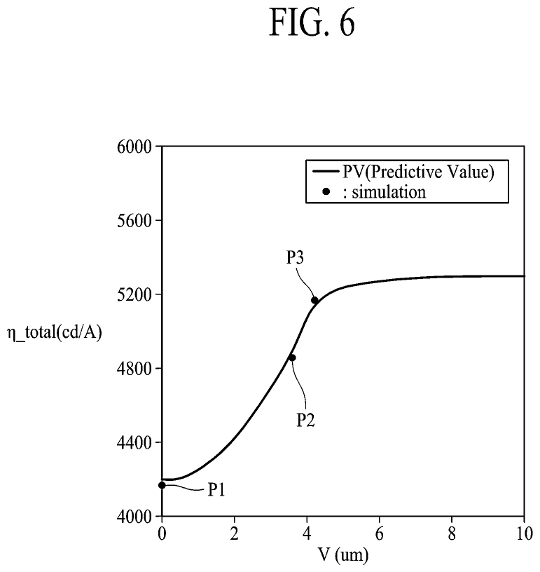

In the above equation, A is a light conversion constant. The light conversion constant A is a value calculated by the inventors through simulation of the total output amount of light emitted from the display apparatus. For example, the light conversion constant A may be about 985. This is described in more detail later with reference to FIG. 6.

The term n_{OLED} may be a refractive index of the light emitting layer 116. The term n_{b} may be a refractive index of the bank 115.

V may be a vertical length from an upper surface of the light emitting layer 116 to a point at which the bank 115 ends. As shown in FIG. 3, V may be a depth of a portion of the reflective portion 130 disposed in the non-light emission area NEA. For convenience of description, a depth of a portion of the reflective portion 130 disposed in the non-light emission area NEA may be defined as the depth V of the reflective portion 130. The depth V of the reflective portion 130 may be expressed as a vertical length from an extension line of a lower surface of the reflective electrode 117 on the light emitting layer 116 of the light emission area EA to a point at which the bank 115 ends in the non-light emission area NEA. In this case, as shown in FIG. 3, the point at which the bank 115 ends may refer to an end (or one end) of the bank 115 spaced apart from the light emission area EA. The vertical length may be a length in a direction parallel to a third direction (Z-axis direction). The third direction (Z-axis direction) may be a direction along a thickness of the display apparatus.

The term h may be the horizontal length from the end of the light emission area EA to the point at which the bank 115 ends. As shown in FIG. 3, the end of the light emission area EA may be the end of the bank 115 (or the other end of the bank 115) covering the edge of the pixel electrode 114 that exists below the light emitting layer 116. The horizontal length may be a length in a direction parallel to the first direction (X-axis direction). The first direction (X-axis direction) may be a direction perpendicular to the third direction (Z-axis direction). Based on FIG. 1, the first direction (X-axis direction) may be a horizontal direction of the display apparatus. The second direction (Y-axis direction) may be a direction perpendicular to each of the first direction (X-axis direction) and the third direction (Z-axis direction), and may be a vertical direction of the display apparatus based on FIG. 1.

The term I_{OLED}(θ) may be the amount of light emitted from the inside of the light emitting layer 116. The amount of light emitted from the inside of the light emitting layer 116 may include reflective light L1 wave-guided to be incident on the bank 115 and then reflected by the reflective portion 130 (specifically, as shown in FIG. 3, first reflective light L1 totally reflected at or on an interface of the light emitting layer 116 (or an interface between the light emitting layer 116 and the pixel electrode 114 or an interface between the light emitting layer 116 and the reflective electrode 117) to be incident on the bank 115 and then reflected by the reflective portion 130), and second reflective light L2 incident from the light emitting layer 116 to the pixel electrode 114 and reflected by the reflective portion 130. Meanwhile, the term θ may represent an incident angle of light incident on the pixel electrode 114 after being emitted from the light emitting layer 116. The term dθ may represent a differential change in θ.

The term B may be the total output amount of light when there is no reflective portion. In detail, B may be the total output amount of light emitted from the light emitting layer of the display apparatus having no reflective portion and output to the lower surface of the substrate. For example, the total output amount B of light when there is no reflective portion may be about 4191. This is described in more detail later with reference to FIG. 6.

In the display apparatus 100 according to an example embodiment of the present disclosure, the reflective portion 130 disposed in the non-light emission area NEA is provided with an optimal depth (or an optimal height), so that light wave-guided at or on the interface of the light emitting layer 116 and directed toward an adjacent subpixel and light incident from the light emitting layer 116 to the pixel electrode 114 and directed toward an adjacent subpixel may be reflected toward a subpixel for emitting light. Therefore, since the display apparatus 100 according to an example embodiment of the present disclosure may improve light extraction efficiency in the non-light-emission area NEA through the reflective portion 130 provided at the optimal depth in the non-light emission area NEA, the total output amount of light (or light efficiency) may be improved.

Further, in the display apparatus 100 according to an example embodiment of the present disclosure, the total output amount of light emitted from the light emitting layer 116 and output to the substrate 110 may be controlled in accordance with the depth V of the reflective portion 130 disposed in the non-light emission area NEA. For example, in the display apparatus 100 according to an example embodiment of the present disclosure, the depth V of the reflective portion 130 is provided to be deep, so that a reflective area capable of reflecting light may be increased, whereby the total output amount of light may be increased. Therefore, in the display apparatus 100 according to an example embodiment of the present disclosure, the depth V of the reflective portion 130 disposed in the non-light emission area NEA may be provided to be proportional to the total output amount of light emitted from the light emitting layer 116 and output to the substrate 110.

Hereinafter, reference to FIGS. 1 to 3, the display apparatus 100 according to an embodiment of the present specification is described in more detail.

Each of the plurality of subpixels SP according to an example embodiment may include a light emission area EA, a non-light emission area NEA adjacent to the light emission area EA, and a light extraction portion 140. The light extraction portion 140 overlaps the light emission area EA and includes a plurality of concave portions 141. The light emission area EA is an area from which light is emitted, and may be included in the display area DA. The non-light emission area NEA is an area from which light is not emitted, and may be an area adjacent to the light emission area EA. The non-light emission area NEA may be referred to as a peripheral area. The reflective portion 130 may be adjacent to the light extraction portion 140 in the non-light emission area NEA, and may be spaced apart from the light emission area EA.

Therefore, in the display apparatus 100 according to an example embodiment of the present disclosure, since the reflective portion 130 disposed in the non-light emission area NEA may reflect light, which is directed toward the subpixel adjacent thereto among light emitted from the light emission area EA, toward the subpixel SP for emitting light, light efficiency (or light extraction efficiency) of the subpixel SP for emitting light may be improved.

The reflective portion 130 according to an example embodiment may be disposed to be inclined on the pattern portion 120 in the non-light emission area NEA. When the depth V of the reflective portion 130 disposed to be inclined is too low (or small), the reflective area for reflecting light becomes smaller so that reflectance of the light directed toward the adjacent subpixel SP is reduced, whereby light extraction efficiency may be reduced. On the other hand, when the depth V of the reflective portion 130 disposed to be inclined is too deep (or great), the reflective area for reflecting the light may be increased so that reflectance of the light directed toward the adjacent subpixel SP may be increased. However, the reflective portion 130 is positioned to be too close to a line for driving the pixel, so that parasitic capacitance may occur. When parasitic capacitance occurs, a signal for driving the pixel P may be delayed.

Therefore, in the display apparatus 100 according to an example embodiment of the present disclosure, as the depth V of the reflective portion 130 disposed to be inclined in the non-light emission area NEA is provided at an optimal depth, the reflective portion 130 may reflect the light emitted from the light emission area EA and directed toward the adjacent subpixel SP while preventing parasitic capacitance from occurring, whereby the total output amount of light may be improved.

The total output amount ηₜₒₜₐₗ of light in the display apparatus 100 according to an example embodiment of the present disclosure may be derived by the equation related to the light conversion constant A, the refractive index n_{OLED} of the light emitting layer 116, the refractive index n_{b} of the bank 115, the depth V of the reflective portion 130, the horizontal length from the end of the light emission area EA to the point at which the bank 115 ends, that is, a width h of a portion of the reflective portion 130 disposed in the non-light emission area NEA, the amount I_{OLED}(θ) of light emitted from the inside of the light emitting layer 116, and the total output amount B of light in the display apparatus having no reflective portion.

The non-light emission area NEA according to an example may include a first area A1 adjacent to the light emission area EA and a second area A2 adjacent to the first area A1 and spaced apart from the light emission area EA. The first area A1 according to an example may be a bank area in which a bank (or a bank covering an edge of the pixel electrode) defining the light emission area EA is disposed. The second area A2 according to an example may be a bank-less area in which a bank is not disposed.

The pattern portion 120 according to an example may be formed to be concave in the non-light emission area NEA. For example, the pattern portion 120 may be formed to be concave in an overcoat layer 113 (shown in FIG. 2) on the substrate 110. The pattern portion 120 may be disposed to be spaced apart from the light emission area EA. The pattern portion 120 according to an example may be provided to surround the light emission area EA in the form of a slit or a trench. For example, a width of the pattern portion 120 may be formed to be reduced from the reflective portion 130 toward the substrate 110. Further, as shown in FIG. 2, the pattern portion 120 may include an area exposed without being covered by the bank 115. Therefore, the pattern portion 120 may be expressed as terms such as a groove, a slit, a trench, a bank slit and a bank trench. As shown in FIG. 2, the pattern portion 120 may include an inclined surface 120s formed in the first area A1 and a bottom surface 120b extending from the inclined surface 120s to the second area A2.

The reflective portion 130 according to an example may be formed to be inclined (or concave) along a profile of the pattern portion 120 formed to be concave in the non-light emission area NEA, thereby being formed to be concave in the non-light emission area NEA. The reflective portion 130 may be made of a material capable of reflecting light, and may reflect light, which is emitted from the light emission area EA and directed toward the adjacent subpixel SP, toward the light emission area EA for emitting light. As shown in FIG. 2, since the reflective portion 130 is disposed to be inclined on the pattern portion 120 while surrounding the light emission area EA, the reflective portion 130 may be expressed as terms such as a side reflective portion or an inclined reflective portion.

Meanwhile, the display apparatus 100 according to an example embodiment of the present disclosure may be implemented in a bottom emission type in which light emitted from the light emission area EA is emitted to the lower surface of the substrate 110. Therefore, in the display apparatus 100 according to an example embodiment of the present disclosure, the total output amount of light emitted to the lower surface of the substrate 110 may be the light in which direct light emitted from the light emission area EA and directly emitted to the lower surface of the substrate 110 and reflective light obtained by reflecting the light, which is emitted from the light emission area EA and directed toward the adjacent subpixel SP, by the reflective portion 130 and emitting the light to the lower surface of the substrate 110 are combined with each other. Therefore, the display apparatus 100 according to an example embodiment of the present disclosure may enhance light extraction efficiency more than a display apparatus in which the reflective portion 130 formed to be concave is not provided.

In the display apparatus having no reflective portion 130, direct light emitted from the light emission area and directly output to the lower surface of the substrate may be the total output amount of light. That is, in the display apparatus having no reflective portion 130, since there is no reflective light reflected and emitted by the reflective portion, only the direct light may be the total output amount of light. This may be the output amount of light, which corresponds to B in the equation to which the display apparatus 100 according to an example embodiment of the present disclosure is applied.

Referring to FIGS. 1 and 2, the display apparatus 100 according to an example embodiment of the present disclosure may include a display panel having a gate driver GD, a light extraction portion 140 overlapping a light emission area EA, a plurality of lines 150, a source drive integrated circuit (which may be referred to as “IC”) 160, a flexible film 170, a circuit board 180, and a timing controller 190.

The display panel may include a substrate 110 and an opposite substrate 200 (shown in FIG. 2).

The substrate 110 may include a thin film transistor, and may be a transistor array substrate, a lower substrate, a base substrate, or a first substrate. The substrate 110 may be a transparent glass substrate or a transparent plastic substrate. The substrate 110 may include, or may be provided in or at, a display area DA and a non-display area NDA.

The display area DA is an area where an image is displayed, and may be a pixel array area, an active area, a pixel array unit, a display unit, or a screen. For example, the display area DA may be disposed at a central portion of the display panel. The display area DA may include a plurality of pixels P.

The opposite substrate 200 may encapsulate (or seal) the display area DA disposed on the substrate 110. For example, the opposite substrate 200 may be bonded to the substrate 110 via an adhesive member (or clear glue). The opposite substrate 200 may be an upper substrate, a second substrate, or an encapsulation substrate.

The gate driver GD supplies gate signals to the gate lines in accordance with the gate control signal input from the timing controller 190. The gate driver GD may be formed on one side of the light emission area EA or in the non-light emission area NEA outside both sides of the light emission area EA in a gate driver in panel (GIP) configuration, as shown in FIG. 1.

The non-display area NDA is an area on which an image is not displayed, and may be a peripheral area, a signal supply area, an inactive area or a bezel area. The non-display area NDA may be configured to be in the vicinity of the display area DA. That is, the non-display area NDA may be disposed to surround the display area DA.

A pad area PA may be disposed in the non-display area NDA. The pad area PA may supply a power source and/or a signal for outputting an image to the pixel P provided in the display area DA. Referring to FIG. 1, the pad area PA may be provided above the display area DA.

The source drive IC 160 receives digital video data and a source control signal from the timing controller 190. The source drive IC 160 converts the digital video data into analog data voltages in accordance with the source control signal and supplies the analog data voltages to the data lines. When the source drive IC 160 is manufactured as a driving chip, the source drive IC 160 may be packaged in the flexible film 170 in a chip on film (COF) configuration or a chip on plastic (COP) configuration.

Pads, such as data pads, may be formed in the non-display area NDA of the display panel. Lines connecting the pads with the source drive IC 160 and lines connecting the pads with lines of the circuit board 180 may be formed in the flexible film 170. The flexible film 170 may be attached to the pads by using an anisotropic conducting film, whereby the pads may be connected to the lines of the flexible film 170.

The circuit board 180 may be attached to the flexible films 170. A plurality of circuits implemented as driving chips may be packaged in the circuit board 180. For example, the timing controller 190 may be packaged in the circuit board 180. The circuit board 180 may be a printed circuit board or a flexible printed circuit board.

The timing controller 190 receives the digital video data and a timing signal from an external system board through a cable of the circuit board 180. The timing controller 190 generates a gate control signal for controlling an operation timing of the gate driver GD and a source control signal for controlling the source drive ICs 160 based on the timing signal. The timing controller 190 supplies the gate control signal to the gate driver GD, and supplies the source control signal to the source drive ICs 160.

Referring to FIG. 2, the substrate 110 according to an example may include, or may be provided in, the light emission area EA and the non-light emission area NEA.

The light emission area EA is an area from which light is emitted, and may be an area that is not covered by a bank 115. A light emitting element layer E, which includes a pixel electrode 114, a light emitting layer 116 and a reflective electrode 117, may be disposed in the light emission area EA. When an electric field is formed between the pixel electrode 114 and the reflective electrode 117, the light emitting layer 116 in the light emission area EA may emit light.

As shown in FIG. 2, a portion of the light emitted from the light emitting layer 116 may be wave-guided by being totally reflected by a difference in refractive index between the light emitting layer 116 and the reflective electrode 117 on the light emitting layer 116 and a difference in refractive index difference between the light emitting layer 116 and the pixel electrode 114 below the light emitting layer 116. The wave-guided light may form an optical path toward an adjacent subpixel along the interface of the light emitting layer 116. In the display apparatus according to an example embodiment of the present disclosure, the reflective portion 130 may be disposed between (or in each of) the subpixels SP to reflect the light, which is directed toward the adjacent subpixel, toward the subpixel for emitting light. Therefore, the display apparatus 100 according to an example embodiment of the present disclosure may improve light efficiency of the subpixel for emitting light by extracting the light, which is dissipated by the wave-guide, by the reflective portion 130. Further, in the display apparatus 100 according to an example embodiment of the present disclosure, the reflective portion 130 disposed between the subpixels SP may prevent color mixture caused by the wave-guide from occurring.

For example, as shown in FIG. 2, the light dissipated by the wave-guide occupies about 1% of the total output amount of light. In the display apparatus 100 according to an example embodiment of the present disclosure, light of 1%, which may be dissipated, may be output toward the subpixel SP for emitting light, in the form of the first reflective light L1, through the reflective portion 130, whereby light efficiency may be improved.

Furthermore, as shown in FIG. 2, the light emitted from the light emitting layer 116 and directed toward the adjacent subpixel amounts to about 9% of the total output amount of light. In the display apparatus 100 according to an example embodiment of the present disclosure, light of 9% capable of generating color mixture may be output toward the subpixel SP for emitting light through the reflective portion 130 in the form of the second reflective light L2, whereby light efficiency may be maximized.

As a result, the display apparatus 100 according to an example embodiment of the present disclosure may improve the total output amount of light by about 10% while preventing color mixture with the adjacent subpixel from occurring through the reflective portion 130.

Referring back to FIG. 2, the light emission area EA according to an example may include gate lines, data lines, pixel driving power lines, and a plurality of pixels P. Each of the plurality of pixels P may include a plurality of subpixels SP that may be defined by the gate lines and the data lines.

Meanwhile, according to an example, at least four subpixels, which are provided to emit different colors and disposed to be adjacent to one another, among the plurality of subpixels SP may constitute one pixel P (or unit pixel). One pixel P may include, but is not limited to, a red subpixel, a green subpixel, a blue subpixel and a white subpixel. One pixel P may include three subpixels SP provided to emit light of different colors and disposed to be adjacent to one another. For example, one pixel P may include a red subpixel, a green subpixel and a blue subpixel.

Each of the plurality of subpixels SP includes a thin film transistor and a light emitting element layer E connected to the thin film transistor. Each of the plurality of subpixels may include a light emitting layer (or an organic light emitting layer) interposed between the pixel electrode and the reflective electrode.

The light emitting layer respectively disposed in the plurality of subpixels SP may individually emit light of different colors or emit white light in common. Since the light emitting layer of each of the plurality of subpixels SP commonly emits white light, each of the red subpixel, the green subpixel and the blue subpixel may include a color filter CF (or wavelength conversion member CF) for converting white light into light of its respective different color. In this case, the white subpixel may not include a color filter.

In the display apparatus 100 according to an example embodiment of the present disclosure, an area provided with a red color filter may be a red subpixel or a first subpixel, an area provided with a green color filter may be a green subpixel or a second subpixel, an area provided with a blue color filter may be a blue subpixel or a third subpixel, and an area in which the color filter is not provided may be a white subpixel or a fourth subpixel.

Each of the subpixels SP supplies a predetermined current to the organic light emitting element in accordance with a data voltage of the data line when a gate signal is input from the gate line by using the thin film transistor. For this reason, the light emitting layer of each of the subpixels may emit light with a predetermined brightness in accordance with the predetermined current.

The plurality of subpixels SP according to an example may be disposed to be adjacent to each other in a first direction (X-axis direction). The first direction (X-axis direction) may be a horizontal direction as illustrated in FIG. 1. The horizontal direction may be a direction in which a gate line is disposed.

A second direction (Y-axis direction) is a direction crossing the first direction (X-axis direction), and may be a vertical direction as illustrated in FIG. 1. The vertical direction may be a direction in which a data line is disposed.

A third direction (Z-axis direction) is a direction crossing each of the first direction (X-axis direction) and the second direction (Y-axis direction), and may be a thickness direction of the display apparatus 100.

The plurality of subpixels SP may include a first subpixel SP1, a second subpixel SP2, a third subpixel SP3 and a fourth subpixel SP4 arranged adjacent to each other in the first direction (X-axis direction). For example, the first subpixel SP1 may be a red subpixel, the second subpixel SP2 may be a green subpixel, the third subpixel SP3 may be a blue subpixel and the fourth subpixel SP4 may be a white subpixel, but is not limited thereto. However, the arrangement order of the first subpixel SP1, the second subpixel SP2, the third subpixel SP3 and the fourth subpixel SP4 may be changed.

Each of the first to fourth subpixels SP1 to SP4 may include a light emission area EA and a circuit area. The light emission area EA may be disposed at one side (or an upper side) of a subpixel area, and the circuit area may be disposed at the other side (or a lower side) of the subpixel area. For example, the circuit area may be disposed at the lower side of the light emission area EA with respect to the second direction Y. The light emission areas EA of the first to fourth subpixels SP1 to SP4 may have the same size (or area) as each other, or different sizes (or areas) from each other.

The first to fourth subpixels SP1 to SP4 may be disposed to be adjacent to one another along the first direction (X-axis direction). For example, two data lines extended along the second direction (Y-axis direction) may be disposed in parallel to each other between the first subpixel SP1 and the second subpixel SP2 and between the third subpixel SP3 and the fourth subpixel SP4. A pixel power line extended along the first direction (X-axis direction) may be disposed between the light emission area EA and the circuit area of each of the first to fourth subpixels SP1 to SP4. The gate line and a sensing line may be disposed below the circuit area. The pixel power line EVDD (shown in FIG. 2) extended along the second direction (Y-axis direction) may be disposed at one side of the first subpixel SP1 or the fourth subpixel SP4. A reference line extended along the second direction (Y-axis direction) may be disposed between the second subpixel SP2 and the third subpixel SP3. The reference line may be used as a sensing line for sensing a change of characteristics of a driving thin film transistor which is disposed in the circuit area and/or a change of characteristics of the light emitting element layer, from the outside in a sensing driving mode of the pixel P. The data lines, the pixel power line EVDD and the reference line may be included in the plurality of lines 150. The data lines may include a first data line DL1 for driving the first subpixel SP1, a second data line DL2 for driving the second subpixel SP2, a third data line for driving the third subpixel SP3 and a fourth data line for driving the fourth subpixel SP4.

A plurality of lines 150 may be provided below the pattern portion 120. Each of the plurality of lines 150 may at least partially overlap the pattern portion 120 below the pattern portion 120. For example, as shown in FIG. 2, the first data line DL1 may partially overlap the bottom surface 120b of the pattern portion 120 between the first subpixel SP1 and the second subpixel SP2. The second data line DL2 may partially overlap the inclined surface 120s of the pattern portion 120. The pixel power line EVDD or the reference line may partially overlap the bottom surface 120b and the inclined surface 120s of the pattern portion 120.

In the display apparatus 100 according to an example embodiment of the present disclosure, each of the plurality of subpixels SP may include the light extraction portion 140. The light extraction portion 140 may be formed on the overcoat layer 113 (shown in FIG. 2) to overlap the light emission area EA of the subpixel. The light extraction portion 140 may be formed on the overcoat layer 113 of the light emission area EA to have a curved (or uneven) shape, thereby changing a propagation path of light emitted from the light emitting element layer E to increase light extraction efficiency. For example, the light extraction portion 140 may be a non-flat portion, an uneven pattern portion, a micro lens portion, or a light scattering pattern portion.

The light extraction portion 140 may include a plurality of concave portions 141. The plurality of concave portions 141 may be formed to be concave inside the overcoat layer 113. For example, the plurality of concave portions 141 may be formed or configured to be concave from an upper surface 1131a of a first layer 1131 included in the overcoat layer 113. Therefore, the first layer 1131 may include a plurality of concave portions 141. The first layer 1131 may be disposed between the substrate 110 and the light emitting element layer E in the third direction (Z-axis direction). The concave portions 141 may be disposed adjacent to the pattern portion 120 in the first direction (X-axis direction).

A second layer 1132 of the overcoat layer 113 may be disposed between the first layer 1131 and a light emitting element layer E (or a pixel electrode 114 shown in FIG. 2). The second layer 1132 according to an example may be formed to be wider than the pixel electrode 114 in a first direction (X-axis direction). Thus, a portion of the second layer 1132 may overlap the light emissive area EA, and the other portion of the second layer 1132 may be in contact with a portion of the bottom surface 120b while covering the inclined surface 120s of the pattern portion 120. That is, as shown in FIG. 2, the second layer 1132 may be extended from the light emission area EA to the first area A1 and thus may be in contact with a portion of the bottom surface 120b while covering the inclined surface 120s of the pattern portion 120. Since an upper surface 1132a of the second layer 1132 is provided flat, the pixel electrode 114 disposed on the upper surface 1132a of the second layer 1132 may also be provided flat. The light emitting layer 116 may be disposed on the second layer 1132.

Meanwhile, a refractive index of the second layer 1132 may be greater than that of the first layer 1131. Therefore, as shown in FIG. 2, a path of light emitted from a light emitting layer 116 and directed toward the substrate 110 may be changed toward the reflective portion 130 due to a difference in refractive indexes between the second layer 1132 and the first layer 1131 of the light extraction portion 140. Therefore, the light having a path formed in the reflective portion 130 by the light extraction portion 140 may be reflected in the reflective portion 130 and emitted toward the light emission area EA of the subpixel SP for emitting light. Hereinafter, the light reflected in the reflective portion 130 and emitted toward the substrate 110 may be defined as the reflective light.

As shown in FIG. 2, the reflective light may include first reflective light L1 (or WG mode extraction light L1) reflected from the reflective portion 130 and emitted to the substrate 110 after being wave-guided through total reflection between the pixel electrode 114 and the reflective electrode 117, second reflective light L2 reflected from the reflective portion 130 and emitted to the substrate 110 after being emitted from the light emitting layer 116 and incident on the pixel electrode 114, and third reflective light L3 (or substrate mode extraction light L3) emitted from the light emitting layer 116, primarily reflected by the reflective portion 130, secondarily reflected on a boundary surface between the lower surface of the substrate 110 and an air layer, thirdly reflected by the reflective portion 130 and then emitted to the substrate 110. The first reflective light L1, the second reflective light L2 and the third reflective light L3, which are shown in solid lines in FIG. 2, may be the reflective light extracted by being reflected by the reflective portion 130. Although not shown, the reflective light may further include reflective light reflected by the reflective portion 130 and emitted to the substrate 110 after its path is changed by the light extraction portion 140.

As shown in FIG. 2, the first reflective light L1 and the second reflective light L2 according to an example may be emitted from a position spaced apart from the light emission area EA. That is, the first reflective light L1 and the second reflective light L2 may be emitted from the non-light emission area NEA or its peripheral area, but the present disclosure is not limited thereto. The first reflective light L1 and/or the second reflective light L2 may be emitted from the light emission area EA. The third reflective light L3 may be emitted from the light emission area EA or the non-light emission area NEA.

The display apparatus 100 according to an example embodiment of the present disclosure may further include light which is emitted to the substrate 110 through the light extraction portion 140 without being reflected by the reflective portion 130. For example, as shown by the dotted line in FIG. 2, the display apparatus 100 may further include primary extraction light L4 emitted from the light emitting layer 116, refracted on a boundary surface between the plurality of concave portions 141 included in the light extraction portion 140 and the first layer 1131 and then emitted to the substrate 110, and recycle light L5 emitted from the light emitting layer 116, primarily refracted on the boundary surface between the plurality of concave portions 141 and the first layer 1131, secondarily reflected on the lower surface of the pixel electrode 114, refracted on the boundary surface between the plurality of concave portions 141 and the first layer 1131 and then emitted to the substrate 110. Therefore, the display apparatus 100 according to an example embodiment of the present disclosure may improve the overall light extraction efficiency through the light extraction portion 140 and the reflective portion 130.

In the display apparatus 100 according to an example embodiment of the present disclosure, since the pattern portion 120 is disposed to surround the light emission area EA, at least a portion of the reflective portion 130 on the pattern portion 120 may be disposed to surround the light emission area EA. Therefore, the reflective light may be emitted toward the substrate 110 from the position spaced apart from the light emission area EA or from the light emission area EA while surrounding at least a portion of the light emission area EA. Therefore, in the display apparatus 100 according to an example embodiment of the present disclosure, since light dissipated by waveguide (or optical waveguide) and/or light dissipated by the interface total reflection may be emitted from the non-light emission area NEA in the form of reflective light through the reflective portion 130 surrounding at least a portion of the light emission area EA, light extraction efficiency may be improved and the overall light emission efficiency may be increased.

A structure of each of the plurality of subpixels SP is described in further detail below.

Referring to FIG. 2, the display apparatus 100 according to an example embodiment of the present disclosure may further include a buffer layer BL, a circuit element layer, a thin film transistor (not shown), a pixel electrode 114, a bank 115, a light emitting layer 116, a reflective electrode 117, an encapsulation layer 118 and a color filter CF.

In more detail, each of the subpixels SP according to an example embodiment may include a circuit element layer provided on an upper surface of a buffer layer BL, including a gate insulating layer (not shown), an interlayer insulating layer 111 and a passivation layer 112, an overcoat layer 113 provided on the circuit element layer, a pixel electrode 114 provided on the overcoat layer 113, a bank 115 covering an edge of the pixel electrode 114, a light emitting layer 116 on the pixel electrode 114 and the bank 115, a reflective electrode 117 on the light emitting layer 116, and an encapsulation layer 118 on the reflective electrode 117.

The thin film transistor for driving the subpixel SP may be disposed on the circuit element layer. The circuit element layer may be expressed in terms of an inorganic film layer. The pixel electrode 114, the light emitting layer 116 and the reflective electrode 117 may be included in the light emitting element layer E.

The buffer layer BL may be formed between the substrate 110 and the gate insulating layer to protect the thin film transistor. The buffer layer BL may be disposed on the entire surface (or front surface) of the substrate 110. The pixel power line EVDD for pixel driving may be disposed between the buffer layer BL and the passivation layer 112. The buffer layer BL may serve to block diffusion of a material contained in the substrate 110 into a transistor layer during a high temperature process of a manufacturing process of the thin film transistor. Optionally, the buffer layer BL may be omitted in some cases.

The thin film transistor (or a drive transistor) according to an example may include an active layer, a gate electrode, a source electrode, and a drain electrode. The active layer may include a channel area, a drain area and a source area, which are formed in a thin film transistor area of a circuit area of the subpixel SP. The drain area and the source area may be spaced parallel to each other with the channel area interposed therebetween.

The active layer may be formed of a semiconductor material based on any one of amorphous silicon, polycrystalline silicon, oxide and organic material.

The gate insulating layer may be formed on the channel area of the active layer. As an example, the gate insulating layer may be formed in an island shape only on the channel area of the active layer, or may be formed on an entire front surface of the substrate 110 or the buffer layer BL, which includes the active layer.

The gate electrode may be formed on the gate insulating layer to overlap the channel area of the active layer.

The interlayer insulating layer 111 may be formed to partially overlap the gate electrode and the drain area and source area of the active layer. The interlayer insulating layer 111 may be formed over the entire light emission area where light is emitted in the circuit area and the subpixel SP.

The source electrode may be electrically connected to the source area of the active layer through a source contact hole provided in the interlayer insulating layer overlapped with the source area of the active layer. The drain electrode may be electrically connected to the drain area of the active layer through a drain contact hole provided in the interlayer insulating layer 111 overlapped with the drain area of the active layer.

The drain electrode and the source electrode may be made of the same metal material. For example, each of the drain electrode and the source electrode may be made of a single metal layer, a single layer of an alloy or a multi-layer of two or more layers, which is the same as or different from that of the gate electrode.

In addition, the circuit area may further include first and second switching thin film transistors disposed together with the thin film transistor, and a capacitor. Since each of the first and second switching thin film transistors is provided on the circuit area of the subpixel SP to have the same structure as that of the thin film transistor, its description may be omitted. The capacitor (not shown) may be provided in an overlap area between the gate electrode and the source electrode of the thin film transistor, which overlap each other with the interlayer insulating layer 111 interposed therebetween.

Additionally, in order to prevent a threshold voltage of the thin film transistor provided in a pixel area from being shifted by light, the display panel or the substrate 110 may further include a light shielding layer (not shown) provided below the active layer of at least one of the thin film transistor, the first switching thin film transistor or the second switching thin film transistor. The light shielding layer may be disposed between the substrate 110 and the active layer to shield light incident on the active layer through the substrate 110, thereby minimizing a change in the threshold voltage of the transistor due to external light. Further, since the light shielding layer is provided between the substrate 110 and the active layer, the thin film transistor may be prevented from being seen by a user.

The passivation layer 112 may be provided on the substrate 110 to cover the pixel area. The passivation layer 112 covers a drain electrode, a source electrode and a gate electrode of the thin film transistor, and the buffer layer. The reference line may be disposed between the passivation layer 112 and the interlayer insulating layer 111. The reference line may be disposed at a position symmetrical to the pixel power line EVDD based on the light emission area EA or a similar position symmetrical to the pixel power line EVDD. Therefore, the reference line and the pixel power line EVDD may be disposed below the bank 115 without covering the light emitting area EA. The passivation layer 112 may be formed over the circuit area and the light emission area. The passivation layer 112 may be omitted. The color filter CF may be disposed on the passivation layer 112.

The overcoat layer 113 may be provided on the substrate 110 to cover the passivation layer 112 and the color filter CF. When the passivation layer 112 is omitted, the overcoat layer 113 may be provided on the substrate 110 to cover the circuit area. The overcoat layer 113 may be formed in the circuit area in which the thin film transistor is disposed and the light emission area EA. In addition, the overcoat layer 113 may be formed in the other non-display area NDA except a pad area PA of the non-display area NDA and the entire display area DA. For example, the overcoat layer 113 may include an extension portion (or an enlarged portion) extended or enlarged from the display area DA to the other non-display area NDA except the pad area PA. Therefore, the overcoat layer 113 may have a size relatively wider than that of the display area DA. The first layer 1131 of the overcoat layer 113 may be provided to have a relatively larger size than the display area DA.

The overcoat layer 113 according to an example may be formed to have a relatively thick thickness, thereby providing a flat surface on the display area DA and the non-display area NDA. For example, the overcoat layer 113 may be made of an organic material such as photo acryl, benzocyclobutene, polyimide and fluorine resin.

The overcoat layer 113 formed in the display area DA (or the light emission area EA) may include a plurality of concave portions 141. The plurality of concave portions 141 are the elements of the light extraction portion 140 for increasing light efficiency of the light emission area EA, and may be formed inside the overcoat layer 113. In detail, as shown in FIG. 2, the plurality of concave portions 141 may be formed in a concave shape on the first layer 1131 of the overcoat layer 113. The plurality of concave portions 141 are provided to be connected to each other so that an embossed shape may be formed in the first layer 1131.

The second layer 1132 having a refractive index higher than that of the first layer 1131 may be formed on the first layer 1131. A path of the light, which is directed toward the adjacent subpixel SP, among the light emitted from the light emitting element layer E may be changed toward the reflective portion 130 in accordance with a difference in the refractive index between the second layer 1132 and the first layer 1131. The second layer 1132 may be provided to cover the embossed shape of the first layer 1131 and thus the upper surface 1132a may be provided to be flat.

The pixel electrode 114 is formed on the upper surface 1132a of the second layer 1132 so that the pixel electrode 114 may be provided to be flat, and the light emitting layer 116 and the reflective electrode 117, which are formed on the pixel electrode 114, may be provided to be also flat. Since the pixel electrode 114, the light emitting layer 116, the reflective electrode 117, that is, the light emitting element layer E is provided to be flat in the light emission area EA, a thickness of each of the pixel electrode 114, the light emitting layer 116 and the reflective electrode 117 in the light emission area EA may be uniformly formed. Therefore, the light emitting layer 116 may be uniformly emitted without deviation in the light emission area EA.

The plurality of concave portions 141 may be formed on the first layer 1131 through a photolithographic process using a mask having an opening portion and then a pattern (or etching) or ashing process after the first layer 1131 is coated to cover the passivation layer 112 and the color filter CF. The plurality of concave portions 141 may be formed in an area overlapped with the color filter CF and/or an area that is not overlapped with the bank 115 of the non-light emission area NEA, but the present disclosure is not limited thereto. A portion of the plurality of concave portions 141 may be formed to overlap the bank 115.

Referring back to FIG. 2, the color filter CF disposed in the light emission area EA may be provided between the substrate 110 and the overcoat layer 113. Therefore, the color filter CF may be disposed between the pixel power line EVDD, for example, the pixel power line EVDD and the reflective portion 130 or between the pixel driving line and the pattern portion 120. The color filter CF may include a red color filter (or a first color filter) CF1 for converting white light emitted from the light emitting layer 116 into red light, a green color filter (or a second color filter) CF2 for converting white light into green light, and a blue color filter (or a third color filter) for converting white light into blue light. The fourth subpixel, which is a white subpixel, may not include a color filter since the light emitting layer 116 emits white light.

As shown in FIG. 2, the display apparatus 100 according to an example embodiment of the present disclosure may be provided such that color filters having different colors partially overlap each other at a boundary portion of the plurality of subpixels SP. In this case, the display apparatus 100 according to an example embodiment of the present disclosure may prevent the light emitted from each subpixel SP from being emitted to the adjacent subpixel SP due to the color filters overlapped with each other at the boundary portion of the subpixels SP, thereby preventing color mixture between the subpixels SP from occurring.

The pixel electrode 114 of the subpixel SP may be formed on the overcoat layer 113. The pixel electrode 114 may be connected to a drain electrode or a source electrode of the thin film transistor through a contact hole passing through the overcoat layer 113 and the passivation layer 112. The edge portion of the pixel electrode 114 may be covered by the bank 115.

Because the display apparatus 100 according to an embodiment of the present disclosure is configured as the bottom emission type, the pixel electrode 114 may be formed of a transparent conductive material (or TCO), such as indium tin oxide (ITO) or indium zinc oxide (IZO) capable of transmitting light, or a semi-transmissive conductive material such as magnesium (Mg), silver (Ag), or an alloy of Mg and Ag.

Meanwhile, the material constituting the pixel electrode 114 may include molybdenum and titanium (or MoTi). The pixel electrode 114 may be a first electrode or an anode electrode.

The bank 115 is an area from which light is not emitted, and may be provided to surround each of the light emitting portions (or the concave portions 141) of each of the plurality of subpixels SP. That is, the bank 115 may partition (or define) the concave portions 141 of each of the light emitting portion or the subpixels SP. The light emitting portion may mean a portion where the pixel electrode 114 and the reflective electrode 117 are in contact with each of the upper surface and the lower surface of the light emitting layer 116 with the light emitting layer 116 interposed therebetween.

The bank 115 may be formed to cover the edge of each pixel electrode 114 of each of the subpixels SP and expose a portion of each of the pixel electrodes 114. That is, the bank 115 may partially cover the pixel electrode 114. Therefore, the bank 115 may prevent the pixel electrode 114 and the reflective electrode 117 from being in contact with each other at the end of each pixel electrode 114. The exposed portion of the pixel electrode 114, which is not covered by the bank 115, may be included in the light emitting portion (or the light emission area EA). As shown in FIG. 2, the light emitting portion may be formed on the plurality of concave portions 141, and thus the light emitting portion (or the light emission area EA) may overlap the concave portions 141 in a thickness direction (or the third direction (Z-axis direction)) of the substrate 110.

After the bank 115 is formed, the light emitting layer 116 may be formed to cover the pixel electrode 114 and the bank 115. Therefore, the bank 115 may be provided between the pixel electrode 114 and the light emitting layer 116. The bank 115 may be referred to as a pixel defining layer. The bank 115 according to an example may include an organic material and/or an inorganic material. As shown in FIG. 2, the bank 115 may be formed to be concave or inclined along the profile of the pattern portion 120 (or the second layer 1132).

Referring again to FIG. 2, the light emitting layer 116 may be formed on the pixel electrode 114 and the bank 115. The light emitting layer 116 may be provided between the pixel electrode 114 and the reflective electrode 117. Thus, when a voltage is applied to each of the pixel electrode 114 and the reflective electrode 117, an electric field is formed between the pixel electrode 114 and the reflective electrode 117. Therefore, the light emitting layer 116 may emit light. The light emitting layer 116 may be formed of a plurality of subpixels SP and a common layer provided on the bank 115.

The light emitting layer 116 according to an embodiment may be provided to emit white light. The light emitting layer 116 may include a plurality of stacks which emit lights of different colors. For example, the light emitting layer 116 may include a first stack, a second stack, and a charge generating layer (CGL) provided between the first stack and the second stack. The light emitting layer may be provided to emit the white light, and thus, each of the plurality of subpixels SP may include a color filter CF suitable for a corresponding color.

The first stack may be provided on the pixel electrode 114 and may be implemented a structure where a hole injection layer (HIL), a hole transport layer (HTL), an emission layer (EML(B)), and an electron transport layer (ETL) are sequentially stacked.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant.

The second stack may be provided on the first stack and may be implemented in a structure where a hole transport layer (HTL), a yellow-green (YG) emission layer (EML(YG)), and an electron injection layer (EIL) are sequentially stacked.

In the display apparatus 100 according to an embodiment of the present disclosure, because the light emitting layer 116 is provided as a common layer, the first stack, the charge generating layer, and the second stack may be arranged all over the plurality of subpixels SP.

The reflective electrode 117 may be formed on the light emitting layer 116. The reflective electrode 117 may be disposed in the light emission area EA and the non-light emission area NEA. The reflective electrode 117 according to an example may include a metal material. The reflective electrode 117 may reflect the light emitted from the light emitting layer 116 in the plurality of subpixels SP toward the lower surface of the substrate 110. Therefore, the display apparatus 100 according to an example embodiment of the present disclosure may be implemented as a bottom emission type display apparatus.

The display apparatus 100 according to an example embodiment of the present disclosure is a bottom emission type and hence reflects light emitted from the light emitting layer 116 toward the substrate 110, and thus the reflective electrode 117 may be made of a metal material having high reflectance. The reflective electrode 117 according to an example may be formed of a metal material having high reflectance such as a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy may be an alloy such as silver (Ag), palladium (Pd) and copper (Cu). The reflective electrode 117 may be expressed as terms such as a second electrode, a cathode electrode and a counter electrode.

Meanwhile, in the display apparatus 100 according to an example embodiment of the present disclosure, the reflective portion 130 may be a portion of the reflective electrode 117. Therefore, the reflective portion 130 may reflect light, which is directed toward the adjacent subpixel SP, toward the light emission area EA of the subpixel SP for emitting light. Since the reflective portion 130 is a portion of the reflective electrode 117, as shown in FIG. 2, the reflective portion 130 may be denoted by a reference numeral 117a. In one or more aspects of the present disclosure, the reflective portion 130 may be the reflective electrode 117 that overlaps the pattern portion 120. In particular, the reflective portion 130 may mean the reflective electrode 117 that is inclined while being overlapped with the pattern portion 120. Therefore, as shown in FIG. 3, the reflective portion 130 may reflect light that is directed toward the adjacent subpixel SP, or light that is dissipated through total reflection between interfaces, toward the light emission area EA (or the non-light emission area NEA) of the subpixel SP for emitting light.

The encapsulation layer 118 is formed on the reflective electrode 117. The encapsulation layer 118 serves to prevent oxygen or moisture from being permeated into the light emitting layer 116 and the reflective electrode 117. To this end, the encapsulation layer 118 may include at least one inorganic film and at least one organic film.

Meanwhile, as shown in FIG. 2, the encapsulation layer 118 may be disposed not only in the light emission area EA but also in the non-light emission area NEA. The encapsulation layer 118 may be disposed between the reflective electrode 117 and an opposing substrate 200.

Hereinafter, the pattern portion 120 and the reflective portion 130 of the display apparatus 100 according to an example embodiment of the present disclosure are described in further detail with reference to FIGS. 2 and 3.

In the display apparatus 100 according to an example embodiment of the present disclosure, in order to prevent light extraction efficiency from being reduced as the light emitted from the light emitting layer is partially not emitted to the outside due to total reflection at or on the interface between the light emitting layer and an electrode, the pattern portion 120 may be provided in the periphery (or the non-light emission area NEA) of the light emission area EA, and the reflective portion 130 may be provided on the pattern portion 120. The reflective portion 130 may be disposed to be inclined along a profile of the pattern portion 120.

In the display apparatus 100 according to an example embodiment of the present disclosure, the total output amount ηₜₒₜₐₗ of light may be derived by the equation related to the light conversion constant A, the refractive index n_{OLED} of the light emitting layer 116, the refractive index n_{b} of the bank 115, the depth V of the reflective portion 130, the horizontal length from the end of the light emission area EA to the point at which the bank 115 ends, that is, a width h of a portion of the reflective portion 130 disposed in the non-light emission area NEA, the amount I_{OLED}(θ) of light emitted from the inside of the light emitting layer 116 and the total output amount of light in the display apparatus having no reflective portion.

In the display apparatus 100 according to an example embodiment of the present disclosure, the total output amount ηₜₒₜₐₗ of light may be provided to be proportional to the depth V of the reflective portion 130. Therefore, in the display apparatus 100 according to an example embodiment of the present disclosure, the light, which is not emitted to the outside due to total reflection at or on the interface between the light emitting element layer and the electrode, may be emitted to the outside through the reflective portion 130, whereby overall light extraction efficiency (or light efficiency) may be improved.

Referring to FIG. 2, the pattern portion 120 may be formed to be concave in the first layer 1131 of the overcoat layer 113. As shown in FIG. 2, the pattern portion 120 may be disposed near the non-light emission area NEA. That is, the pattern portion 120 may be disposed to surround the light emission area EA while being adjacent to the light extraction portion 140. The pattern portion 120 may be formed in the non-light emission area NEA in the meanwhile when the plurality of concave portions 141 are formed in the light emission area EA. The pattern portion 120 may include a bottom surface 120b and an inclined surface 120s.

The bottom surface 120b of the pattern portion 120 according to an example embodiment is a surface formed to be closest to the substrate 110, or may be disposed to be closer to the substrate 110 (or the upper surface of the substrate) than the pixel electrode 114 (or the lower surface of the pixel electrode 114) in the light emission area EA. Therefore, as shown in FIG. 3, the bottom surface 120b of the pattern portion 120 may be provided to have a depth equal to or similar to that of each of the plurality of concave portions 141. However, when the depth of the pattern portion 120 is lower than that of the concave portion 141, since an area of the reflective portion 130 is reduced, light extraction efficiency may be reduced. Therefore, in the display apparatus 100 according to an example embodiment of the present disclosure, the depth of the pattern portion 120 may be provided to be equal to or deeper than that of the concave portion 141.

The inclined surface 120s of the pattern portion 120 may be disposed between the bottom surface 120b and the light extraction portion 140. Therefore, the inclined surface 120s of the pattern portion 120 may be provided to surround the light emission area EA or the plurality of concave portions 141. As shown in FIG. 2, the inclined surface 120s may be connected to the bottom surface 120b. The inclined surface 120s may form a predetermined angle with the bottom surface 120b. For example, the angle formed by the inclined surface 120s and the bottom surface 120b may be an obtuse angle. Therefore, a width of the pattern portion 120 may be gradually reduced toward a direction (or the third direction (Z-axis direction)) from the opposing substrate 200 (or the reflective portion 130) toward the substrate 110. As the obtuse angle is formed by the inclined surface 120s and the bottom surface 120b, the light emitting element layer E (or the light emitting element layer E including the reflective portion 130) including the second layer 1132, the bank 115 and the reflective portion 130, which are formed in a subsequent process, may be formed to be concave along the profile of the pattern portion 120. Therefore, the light emitting element layer E may be formed to be concave on the pattern portion 120 formed to be concave in the non-light emission area NEA (or the peripheral area). The light emitting element layer E formed to be concave in the pattern portion 120 may mean that it includes at least one of the pixel electrode 114, the light emitting layer 116 or the reflective electrode 117.

As shown in FIG. 2, the pattern portion 120 may be provided to surround the light emission area EA. As the pattern portion 120 is provided to surround the light emission area EA, at least a portion of the reflective portion 130 disposed to be inclined on the pattern portion 120 may be provided to surround the light emission area EA. Therefore, in the display apparatus 100 according to an example embodiment of the present disclosure, since light may be extracted even from the non-light emission area NEA near the light emission area EA, overall light efficiency may be improved. Therefore, the display apparatus 100 according to an example embodiment of the present disclosure may have the same light emission efficiency or further enhanced light emission efficiency even with low power as compared with a general display apparatus having no pattern portion 120 and reflective portion 130, whereby overall power consumption may be reduced.

In addition, the display apparatus 100 according to an example embodiment of the present disclosure may allow the light emitting element layer E to emit light even with low power, thereby improving lifespan of the light emitting element layer E.

Since the pattern portion 120 is disposed to surround the light emission area EA, the pattern portion 120 may be disposed between the subpixels SP for emitting light of different colors. Therefore, the reflective portion 130 disposed to be inclined on the pattern portion 120 may be disposed between the subpixels SP for emitting light of different colors, whereby the reflective portion 130 may prevent light of different colors from being emitted to other adjacent subpixels SP. Therefore, the display apparatus 100 according to one or more aspects of the present disclosure may prevent color mixture (or color distortion) from occurring between the subpixels SP for emitting light of different colors, thereby improving color purity.

The second layer 1132 of the overcoat layer 113 may be further extended from the light emission area EA to the non-light emission area NEA to partially cover the inclined surface 120s of the pattern portion 120. Therefore, as shown in FIG. 2, an end 1132c of the second layer 1132 may be in contact with the bottom surface 120b of the pattern portion 120. In this case, the end 1132c of the second layer 1132 may be in contact with only a portion of the bottom surface 120b. When the second layer 1132 entirely covers the bottom surface 120b, the depth of the reflective portion 130 formed on the pattern portion 120 may be relatively lowered, thereby reducing reflective efficiency. Therefore, in the display apparatus 100 according to an example embodiment of the present disclosure, the second layer 1132 is provided to be in contact with only a portion of the bottom surface 120b without entirely covering the bottom surface 120b of the pattern portion 120 and thus the reflective portion 130 formed in a subsequent process may be formed to be close to the bottom surface 120b, whereby reflective efficiency may be improved.

The bank 115 may be extended to cover the inclined surface 1132b of the second layer 1132 covering the inclined surface 120s of the pattern portion 120 while covering the edge of the pixel electrode 114. Therefore, the bank 115 may be in contact with a portion of the bottom surface 120b of the pattern portion 120, which is not covered by the second layer 1132. When the bank 115 entirely covers the bottom surface 120b, the depth of the reflective portion 130 formed on the pattern portion 120 is lowered, whereby reflective efficiency may be reduced. Therefore, as shown in FIG. 3, each of the second layer 1132 and the bank 115 at or on the bottom surface 120b of the pattern portion 120 may be discontinuously provided. That is, each of the second layer 1132 and the bank 115 may be disconnected at or on the bottom surface 120b of the pattern portion 120. As a result, in the display apparatus 100 according to an example embodiment of the present disclosure, the bank 115 is provided to be in contact with only a portion of the bottom surface 120b without entirely covering the bottom surface 120b, so that the reflective portion 130 formed in a subsequent process may be formed to be close to the bottom surface 120b, whereby reflective efficiency may be improved.

Since the bank 115 is provided to be in contact with only a portion of the bottom surface 120b of the pattern portion 120, the bank 115 may be disconnected at the pattern portion 120 as shown in FIG. 2. As the bank 115 is disconnected from the pattern portion 120, the reflective portion 130 disposed on the pattern portion 120 may be disposed to be close to the bottom surface 120b of the pattern portion 120. Therefore, the reflective portion 130 may be formed as deep as possible in the pattern portion 120 as compared with the case that the bank is not disconnected from the pattern portion 120, and thus reflective efficiency may be improved. As shown in FIG. 2, since the pattern portion 120 is disposed between the subpixels SP, the second layer 1132, the bank 115, the light emitting layer 116 and the reflective portion 130 may be provided to be symmetrical based on the center of the pattern portion 120 (or the center of the second area A2).

In the display apparatus 100 according to an example embodiment of the present disclosure, the plurality of lines 150 may be disposed so as not to cover the light emission area EA (or so as not to overlap the light emission area EA). When the plurality of lines 150 overlap or cover the light emission area EA, the light reflected by the reflective portion 130 may be blocked by the plurality of lines 150 and thus cannot be emitted toward the substrate 110. Therefore, in the display apparatus 100 according to an example embodiment of the present disclosure, the plurality of lines 150 may be disposed in the non-light emission area NEA so as not to overlap the light emission area EA, whereby light extraction efficiency may be maximized. Furthermore, in the display apparatus 100 according to an example embodiment of the present disclosure, the plurality of lines 150 may be provided so as not to overlap the light emission area EA, whereby an aperture ratio may be enlarged as compared with the case that the plurality of lines overlap the light emission area, and thus luminance may be improved. Although the arrangement structure of the plurality of lines 150 in the first subpixel SP1 and the second subpixel SP2 has been described with reference to FIG. 2, the above-described structure may be equally applied to the third subpixel SP3 and the fourth subpixel SP4. However, a line having a wide width, which is disposed among the first to fourth subpixels may be the reference line.

Meanwhile, as the bank 115 is disconnected from the pattern portion 120, the light emitting layer 116 and the reflective portion 130 (or the reflective electrode 117) formed in a subsequent process may be formed along a profile of the bottom surface 120b of the pattern portion 120 and the bank 115. Accordingly, as shown in FIG. 2, a portion of the light emitting layer 116 may contact the bottom surface 120b of the pattern portion 120.

The reflective portion 130 according to an example may be formed to be concave on the pattern portion 120 along the profile of the pattern portion 120 formed to be concave in or near the non-light emission area NEA, thereby being formed to be concave in or near the non-light emission area NEA. The reflective portion 130 may be made of a material capable of reflecting light to reflect light, which is emitted from the light emission area EA and directed toward the subpixel SP adjacent thereto, toward the light emission area EA of the subpixel SP for emitting light. As shown in FIG. 2, the reflective portion 130 may include a flat surface 131 disposed at a central portion of the second area A2 and an inclined surface 132 connected to the flat surface 131. The flat surface 131 may be disposed in parallel to the bottom surface 120b (shown in FIG. 2) of the pattern portion 120. The inclined surface 132 may be formed to be inclined along the profile of the inclined surface 120s of the pattern portion 120. Most of the light, which is directed toward the subpixel SP adjacent thereto among the light emitted from the subpixel SP for emitting light, may be reflected by the inclined surface 132 of the reflective portion 130 and then emitted to the light emission area EA of the subpixel SP for emitting light or the non-light emission area NEA of the subpixel SP for emitting light.

In the display apparatus 100 according to an example embodiment of the present disclosure, the total output amount of light may be determined in accordance with the depth V of the reflective portion 130 disposed to be inclined in the non-light emission area NEA. For example, when the depth V of the reflective portion 130 is deep, a reflective area capable of reflecting light toward an adjacent subpixel SP is increased, whereby the total output amount of light may be improved.

In the display apparatus 100 according to an example embodiment of the present disclosure, the total output amount ηₜₒₜₐₗ of light may be derived by the equation related to the light conversion constant A, the refractive index n_{OLED} of the light emitting layer 116, the refractive index n_{b} of the bank 115, the depth V of the reflective portion 130, the horizontal length from the end of the light emission area EA to the point at which the bank 115 ends, that is, a width h of a portion of the reflective portion 130 disposed in the non-light emission area NEA, the amount I_{OLED}(θ) of light emitted from the inside of the light emitting layer 116 and the total output amount B of light in the display apparatus having no reflective portion.

For example, the total output amount of light may be provided to satisfy

$${η}_{total} = A {\int }_{0}^{{sin}^{- 1} ( \frac{{n}_{b}}{{n}_{OLED} \cdot \sqrt{1 + {( \frac{h}{v} )}^{2}}} )} {I}_{OLED} ( θ ) d θ + B .$$

In the above equation, A is the light conversion constant, and n_{OLED} is the refractive index of the light emitting layer 116. The term no is the refractive index of the bank 115, V is the vertical length from the upper surface of the light emitting layer 116 to the point at which the bank 115 ends, h is the horizontal length from the end of the light emission area EA to the point at which the bank 115 ends, I_{OLED}(θ) is the amount of light emitted from the inside of the light emitting layer 116, and B is the total output amount of light when there is no reflective portion.

The amount I_{OLED}(θ) of light emitted from the inside of the light emitting layer 116 may be provided to satisfy

$${I}_{OLED} ( θ ) = cos θ \cdot R ( θ ) .$$

The term cos θ may be diffuse reflection. The diffuse reflection may be a conversion value for reflecting characteristics of light scattered when light is reflected. As shown in FIG. 3, θ may be an incident angle of light incident on the pixel electrode 114 after being emitted from the light emitting layer 116. Therefore, the diffuse reflection may be a conversion value for reflecting characteristics of light, which is scattered when light is reflected, in the pixel electrode 114. R(θ) may be the degree of reflection. The degree of reflection may be for simplifying Lambertian emission of light emitted from the light emitting layer 116. The degree of reflection R(θ) may be provided to satisfy

$$R ( θ ) = {r}_{TE}^{2} + {r}_{TM}^{2} .$$

The term r_{TE} may be a reflective coefficient of a vertical component of light incident on the pixel electrode 114 from the light emitting layer 116. The term r_{TM} may be a reflective coefficient of a horizontal component of light incident on the pixel electrode 114 from the light emitting layer 116. The degree of reflection R(θ) is described in more detail with reference to FIG. 4. A horizontal axis of FIG. 4 represents θ. A vertical axis represents values for a transverse magnetic (TM) and a transverse electric (TE), where the maximum value is 1, which is a Fresnel coefficient (or reflective coefficient). A point C of FIG. 4 may be a specific angle at which a transverse magnetic (TM), that is, a horizontal component is 0. A point D may be an angle at which light emitted from the light emitting layer 116 is totally reflected on an upper surface of the pixel electrode 114 (or a lower surface of the reflective electrode 117). As shown in FIG. 4, it can be seen that a transverse electric (TE) is increased until θ is from 90° to 48°, and a TM is reduced from 90° to 55° and is 0 at 55° and then is rapidly increased to reach a point D from 55°. It can be seen that the TE and the TM meet each other at about 48° at which the point D exists, and each of the TE and the TM is maintained at 1, which is a Fresnel coefficient, from about 48° or less. That is, it can be seen that each of the TE and the TM becomes a maximum value at the point D and the maximum value is 1. It is noted from the graph of FIG. 4 that the light emitted from the light emitting layer 116 is totally reflected at the point D, that is, when θ is 48° or less and is partially transmitted toward the pixel electrode 114 when θ exceeds 48°. Therefore, as shown in FIG. 3, a portion of the light emitted from the light emitting layer 116 may be emitted toward the pixel electrode 114 and then directed toward the reflective portion 130 while having an incident angle θ and an emission angle θₜ (or a refractive angle θₜ) based on the boundary surface of the light emitting layer 116 and the pixel electrode 114. For example, the incident angle θ may exceed 48° and may be 90° or less.

As shown in FIG. 3, since the light emitting layer 116 and the pixel electrode 114 have their refractive indexes different from each other, a portion of the light emitted from the light emitting layer 116 may be bent at a predetermined angle while being incident on the pixel electrode 114.

The degree of reflection R(θ) according to another example may be provided to satisfy

$$R ( θ ) = {\vert \frac{{n}_{OLED} sin θ - \text{?} sin {θ}_{t}}{{n}_{OLED} sin θ + \text{?} sin {θ}_{t}} \vert}^{2} + {\vert \frac{\text{?} sin θ - {n}_{OLED} sin {θ}_{t}}{\text{?} sin θ + {n}_{OLED} sin {θ}_{t}} \vert}^{2} .$$

$$\text{?} \text{indicates text missing or illegible when filed}$$

The term n_{OLED} may be the refractive index of the light emitting layer 116, the term n_{ITO} may be the refractive index of the pixel electrode 114, the term θ may be an incident angle of light emitted from the light emitting layer 116 to the pixel electrode 114, and θₜ may be an emission angle of light emitted from the boundary surface between the light emitting layer 116 and the pixel electrode 114 to the inside of the pixel electrode 114.

Since the degree of reflection R(θ) and diffuse reflection cos θ may be derived from the above equations, the amount I_{OLED}(θ) of light emitted from the inside of the light emitting layer 116 may be derived.

Referring back to FIG. 3, a maximum incident angle θ₁ₘₐₓ incident on the bank 115 from the light emitting layer 116 and a maximum emission angle θ₂ₘₐₓ emitted from the inside of the bank 115 (or into the bank 115) may be provided to satisfy

$$sin {θ}_{2 max} = \frac{{n}_{OLED}}{{n}_{b}} sin {θ}_{1 max} .$$

The term n_{b} may be the refractive index of the bank 115. The term n_{OLED} may be the refractive index of the light emitting layer 116. As shown in FIG. 3, since the light emitting layer 116 and the bank 115 have their respective indexes different from each other, a portion of the light emitted from the light emitting layer 116 may be bent at a predetermined angle while being incident on the bank 115. Therefore, the maximum incident angle θ₁ₘₐₓ incident on the bank 115 from the light emitting layer 116 and the maximum emission angle θ₂ₘₐₓ emitted from the inside of the bank 115 (or into the bank 115) may be different from each other.

The maximum emission angle θ₂ₘₐₓ emitted from the inside of the bank 115 (or into the bank 115) may be provided to satisfy

$${θ}_{2 max} {tan}^{- 1} ( \frac{v}{h} ) = {sin}^{- 1} ( \frac{{n}_{OLED}}{{n}_{b}} sin {θ}_{1 max} ) .$$

The term h may be the horizontal length from the end of the light emission area EA to the point at which the bank 115 ends. The term V may be the vertical length from the upper surface of the light emitting layer 116 to the point at which the bank 115 ends, that is, the depth of a portion of the reflective portion 130 disposed in the non-light emission area NEA. The term θ₁ₘₐₓ may be the maximum incident angle at which a portion of light emitted from the light emitting layer 116 is incident on the bank 115.

In this case, the vertical length V from the upper surface of the light emitting layer 116 to the point at which the bank 115 ends may be provided to satisfy

$$V = h tan {θ}_{2 max} .$$

The term h may be the horizontal length from the end of the light emission area EA to the point at which the bank 115 ends. The term θ₂ₘₐₓ may be the maximum emission angle at which a portion of the light emitted from the light emitting layer 116 is emitted from the inside the bank 115 (or into the bank 115).

Since the vertical length V from the upper surface of the light emitting layer 116 to the point at which the bank 115 ends and the maximum emission angle θ₂ₘₐₓ emitted from the inside of the bank 115 (or into the bank 115) may be derived from the above equations, a relation equation between the maximum incident angle θ₁ₘₐₓ incident on the bank 115 from the light emitting layer 116 and the maximum emission angle θ₂ₘₐₓ emitted from the inside of the bank 115 (or into the bank 115) may be derived.

Therefore, in the display apparatus 100 according to an example embodiment of the present disclosure, the total output amount ηₜₒₜₐₗ of light emitted from the light emitting layer 116 and output to the substrate 110 may be provided to satisfy

$${η}_{total} = A {\int }_{0}^{{sin}^{- 1} ( \frac{{n}_{b}}{{n}_{OLED} \cdot \sqrt{1 + {( \frac{h}{v} )}^{2}}} )} {I}_{OLED} ( θ ) d θ + B .$$

That is, since the display apparatus 100 according to an example embodiment of the present disclosure is provided to satisfy the above equation, the total output amount ηₜₒₜₐₗ of light may be provided to be proportional to the depth V of the reflective portion 130 disposed in the non-light emission area NEA.

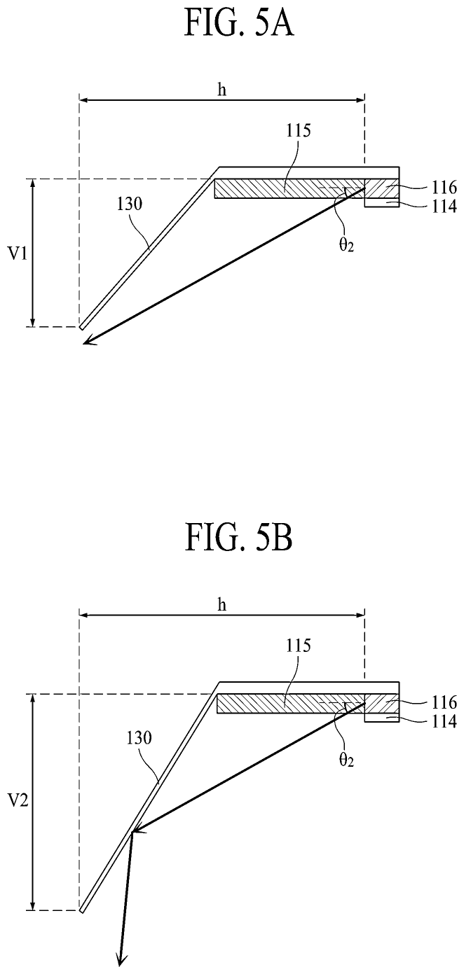

Hereinafter, the relation between the depth V of the reflective portion 130 and the refractive angle (or emission angle) of the light incident on the bank 115 from the light emitting layer 116 is described in more detail with reference to FIGS. 5A and 5B.

FIGS. 5A and 5B are schematic views illustrating a depth of a reflective portion and a refractive angle of light incident on a bank from a light emitting layer of a display apparatus according to an example embodiment of the present disclosure.

FIG. 5A is a comparative example illustrating that a depth V1 of the reflective portion 130 is smaller than h tan θ₂. θ₂ may be an emission angle (or refraction angle) at which the light emitted from the light emitting layer 116 is output from the inside of the bank 115 (or into the bank 115). That is, as shown in FIG. 5A, θ₂ may be an angle (or emission angle) of light bent at or on an extension line parallel to the upper surface of the pixel electrode 114 and the boundary surface between the bank 115 and the light emitting layer 116. The term h may be the horizontal length from the end of the light emission area EA to the point at which the bank 115 ends. Referring to FIG. 2, the point at which the bank 115 ends may be the same as a point at which the inclined reflective portion 130 ends (or is inflected). Therefore, the point at which the bank 115 ends may be a point at which the reflective portion 130 ends in FIG. 5A. Therefore, in FIG. 5A, h may be the horizontal length from the end of the light emission area EA to the point at which the reflective portion 130 ends.

In case of FIG. 5A, since the depth V1 of the reflective portion 130 is smaller than h tan θ₂, the light incident on the bank 115 from the light emitting layer 116 may be output to the adjacent subpixel without being reflected by the reflective portion 130. Therefore, in case of the comparative example in FIG. 5A, color mixture may occur between the subpixels.

On the other hand, FIG. 5B illustrates that a depth V2 of the reflective portion 130 of the display apparatus 100 according to an example embodiment of the present disclosure is greater than h tan θ₂. In case of FIG. 5B, since the depth V2 of the reflective portion 130 is greater than h tan θ₂, the light incident on the bank 115 from the light emitting layer 116 may be reflected by the reflective portion 130 and then emitted toward the subpixel for emitting light. Therefore, the display apparatus 100 according to an example embodiment of the present disclosure may improve light extraction efficiency (or light efficiency) of the subpixel SP for emitting light while preventing color mixture with the adjacent subpixel SP from occurring.

FIG. 6 is a graph illustrating the total output amount of light based on a depth of a reflective portion of a display apparatus according to an example embodiment of the present disclosure.

Referring to FIG. 6, a horizontal axis represents the depth V of the reflective portion 130, and a vertical axis represents the total output amount ηₜₒₜₐₗ of light. FIG. 6 illustrates the total output amount of light based on the depth V of the reflective portion 130 in a state that the horizontal length h from the end of the light emission area EA to the point at which the bank 115 ends is fixed to 7 μm. P1, P2 and P3 are actual measurement values measured by the inventors of the display apparatus of the present disclosure through simulation of the total output amount of light according to the depth V of the reflective portion 130. A predictive value PV is a predictive value obtained by connecting P1, P2 and P3.

As shown in FIG. 6, P1 indicates that the total output amount of light is about 4191 when the depth V of the reflective portion 130 is 0 μm. That is, P1 may be the total output amount of light directly emitted to the lower surface of the substrate 110 in the display apparatus in which the reflective portion 130 is not provided in the non-light emission area NEA. This may be a value corresponding to B in the equation of

$${η}_{total} = A {\int }_{0}^{{sin}^{- 1} ( \frac{{n}_{b}}{{n}_{OLED} \cdot \sqrt{1 + {( \frac{h}{v} )}^{2}}} )} {I}_{OLED} ( θ ) d θ + B .$$

P2 indicates that the total output amount of light is about 4850 when the depth V of the reflective portion 130 is about 3.8 μm. P3 indicates that the total output amount of light is about 5180 when the depth V of the reflective portion 130 is about 4.2 μm.

Since the total output amount of light according to the depth V of the reflective portion 130 at each point of P1, P2 and P3 may be known from the graph of FIG. 6, the light conversion constant A may be derived by applying the total output amount of light to the above equation. The light conversion constant A according to an example may be about 985.

When the measurement values P1, P2 and P3 are connected to one another, as shown in FIG. 6, a graph in which the depth V of the reflective portion 130 is rapidly increased from 0 μm to about 5 μm may be drawn. That is, it can be seen that the total output amount of light is rapidly improved from 4191 to 5180 when the depth V of the reflective portion 130 is from 0 μm to about 5 μm. Further, 989, which is a difference value between 5180 and 4191, may be the output amount of light reflected by the reflective portion 130 and then output to the substrate 110.

As shown in FIG. 6, it can be seen that the total output amount of light is increased without rapid increase when the depth V of the reflective portion 130 exceeds 5 μm. That is, when the depth V of the reflective portion 130 exceeds 5 μm, the total output amount of light is not greatly improved. When the depth V of the reflective portion 130 becomes too deep, the reflective portion 130 is positioned to be too close to the line 150, whereby parasitic capacitance may occur. When a parasitic capacitance occurs, a signal for driving the pixel P (or the subpixel SP) may be delayed.

In addition, when the depth V of the reflective portion 130 exceeds 5 μm, a defect rate due to restriction in the process rather than the total output amount of light may be increased. For example, when the depth V of the reflective portion 130 exceeds 5 μm, since it is difficult to form a concave portion 141 in a first layer 1131, the defect rate of the display apparatus may be increased, whereby yield may be reduced.

Therefore, in the display apparatus 100 according to an example embodiment of the present disclosure, when the horizontal length h from the end of the light emission area EA to the point at which the bank 115 ends is 7 μm, the depth V of the reflective portion 130 may be provided to be 5 μm or less, thereby maximizing the total output amount of light while preventing parasitic capacitance from occurring. Further, in the display apparatus 100 according to an example embodiment of the present disclosure, when the horizontal length h from the end of the light emission area EA to the point at which the bank 115 ends is 7 μm, the depth V of the reflective portion 130 is provided to be 5 μm or less, thereby maximizing the total output amount of light while reducing the defect rate.

According to one or more aspects of the present disclosure, advantageous effects, including one or more of the following effects, may be obtained.

In the display apparatus according to one or more aspects of the present disclosure, as the reflective portion disposed in the non-light-emission area is provided at an optimal depth (or an optimal height), light extraction efficiency may be improved in the non-light-emission area so that the total output amount of light (or light efficiency) may be improved.

In the display apparatus according to one or more aspects of the present disclosure, since the light may be extracted even from the non-light emission area, the display apparatus according to one or more aspects of the present disclosure may have the same light emission efficiency or further enhanced light emission efficiency even with low power as compared with the display apparatus having no reflective portion, whereby overall power consumption may be reduced.

In the display apparatus according to one or more aspects of the present disclosure, each of the plurality of subpixels includes the light extraction portion that includes the plurality of concave portions, so that light extraction efficiency of the light emitted from the light emitting element layer may be maximized.

It will be apparent to those skilled in the art that the present disclosure described above is not limited by the above-described embodiments and the accompanying drawings and that various substitutions, modifications and variations can be made in the present disclosure without departing from the technical idea, spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display apparatus, comprising:
a substrate;
a plurality of pixels having a plurality of subpixels;
a pattern portion disposed on the substrate and formed to be concave between the plurality of subpixels; and
a reflective portion disposed to be inclined on the pattern portion,
wherein:
the plurality of subpixels include a light emission area and a non-light emission area;
the light emission area includes a light emitting layer;
the non-light emission area includes a bank;
the non-light emission area is adjacent to the light emission area; and
a total output amount of light emitted from the light emitting layer and output to the substrate is provided to satisfy
$${η}_{total} = A {\int }_{0}^{{sin}^{- 1} ( \frac{{n}_{b}}{{n}_{OLED} \cdot \sqrt{1 + {( \frac{h}{v} )}^{2}}} )} {I}_{OLED} ( θ ) d θ + B ,$$
where ηₜₒₜₐₗ is the total output amount of light emitted from the light emitting layer and output to the substrate, A is a light conversion constant, n_{OLED} is a refractive index of the light emitting layer, n_{b} is a refractive index of the bank, V is a vertical length from an upper surface of the light emitting layer to a point at which the bank ends, h is a horizontal length from an end of the light emission area to the point at which the bank ends, I_{OLED}(θ) is an amount of light emitted from an inside of the light emitting layer, and B is a total output amount of light when there is no reflective portion.

2. The display apparatus of claim 1, wherein the plurality of subpixels include a pixel electrode below the light emitting layer, and
wherein I_{OLED}(θ) is provided to satisfy I_{OLED}(θ)=cos θ·R(θ),
where cos θ is diffuse reflection, R(θ) is a degree of reflection, and θ is an incident angle of light incident on the pixel electrode after being emitted from the light emitting layer.

3. The display apparatus of claim 2, wherein the degree of reflection is provided to satisfy
$$R ( θ ) = {r}_{TE}^{2} + {r}_{TM}^{2} ,$$
where r_{TE} is a reflective coefficient of a vertical component of the light incident on the pixel electrode from the light emitting layer, r_{TM} is a reflective coefficient of a horizontal component of the light incident on the pixel electrode from the light emitting layer.

4. The display apparatus of claim 2, wherein the degree of reflection is provided to satisfy
$$R ( θ ) = {\vert \frac{{n}_{OLED} sin θ - \text{?} sin {θ}_{t}}{{n}_{OLED} sin θ + \text{?} sin \text{?}} \vert}^{2} + {\vert \frac{\text{?} sin θ - {n}_{OLED} sin {θ}_{t}}{\text{?} sin θ + {n}_{OLED} sin {θ}_{t}} \vert}^{2} ,$$
$$\text{?} \text{indicates text missing or illegible when filed}$$
where n_{ITO} is a refractive index of the pixel electrode, and θₜ is an emission angle of light emitted from a boundary surface between the light emitting layer and the pixel electrode to an inside of the pixel electrode.

5. The display apparatus of claim 2, wherein θ exceeds 48° and is 90° or less.

6. The display apparatus of claim 1, wherein the plurality of subpixels include a pixel electrode below the light emitting layer, and
wherein a maximum incident angle and a maximum emission angle are provided to satisfy
$$sin {θ}_{2 max} = \frac{{n}_{OLED}}{{n}_{b}} sin {θ}_{1 max} ,$$
where θ₁ₘₐₓ is the maximum incident angle at which a portion of light emitted from the light emitting layer is incident on the bank, and θ₂ₘₐₓ is the maximum emission angle at which a portion of light emitted from the light emitting layer is emitted from an inside of the bank.

7. The display apparatus of claim 6, wherein θ₂ₘₐₓ is provided to satisfy
$${θ}_{2 max} {tan}^{- 1} ( \frac{v}{h} ) = {sin}^{- 1} ( \frac{{n}_{OLED}}{{n}_{b}} sin {θ}_{1 max} ) .$$

8. The display apparatus of claim 7, wherein V is provided to satisfy
$$V = h tan {θ}_{2 max} .$$

9. The display apparatus of claim 1, further comprising a reflective electrode on the light emitting layer,
wherein the reflective portion is a portion of the reflective electrode.

10. The display apparatus of claim 1, wherein V is 5 μm or less when h is 7 μm.

11. The display apparatus of claim 1, wherein, the pattern portion is disposed to be spaced apart from the light emission area.

12. The display apparatus of claim 1, wherein a width of the pattern portion is reduced in a direction from the reflective portion toward the substrate.

13. The display apparatus of claim 1, wherein:
the plurality of subpixels include a light extraction portion that overlaps the light emission area and includes a plurality of concave portions;
the non-light emission area includes a first area and a second area;
the first area is adjacent to the light emission area;
the second area is adjacent to the first area and spaced apart from the light emission area;
the light extraction portion is disposed to be adjacent to the pattern portion;
the pattern portion includes an inclined surface and a bottom surface;
the inclined surface is formed in the first area; and
the bottom surface extends from the inclined surface to the second area.

14. The display apparatus of claim 13, wherein the inclined surface of the pattern portion forms an obtuse angle with the bottom surface.

15. The display apparatus of claim 13, wherein:
the plurality of subpixels further include an overcoat layer on the substrate and a pixel electrode on the overcoat layer;
the overcoat layer includes a first layer and a second layer;
the first layer includes the plurality of concave portions;
the second layer is disposed between the first layer and the pixel electrode; and
the second layer is extended to the first area and is in contact with a portion of the bottom surface of the pattern portion while covering the inclined surface of the pattern portion.

16. The display apparatus of claim 1, wherein the pattern portion surrounds the light emission area.

17. The display apparatus of claim 15, wherein the bank covers an edge of the pixel electrode and is disconnected at the bottom surface of the pattern portion.

18. The display apparatus of claim 15, wherein the bank is extended to cover an inclined surface of the second layer covering the inclined surface of the pattern portion and is in contact with a portion of the bottom surface of the pattern portion.

19. The display apparatus of claim 18, wherein each of the second layer and the bank on the bottom surface of the pattern portion is discontinuous.

20. A display apparatus, comprising:
a substrate;
a plurality of pixels having a plurality of subpixels;
a pattern portion disposed on the substrate and formed to be concave between the plurality of subpixels; and
a reflective portion formed to be concave on the pattern portion,
wherein:
the plurality of subpixels include a light emission area and a non-light emission area;
the light emission area includes a light emitting layer;
the non-light emission area is disposed adjacent to the light emission area; and
a depth of the reflective portion disposed in the non-light emission area is proportional to a total output amount of light emitted from the light emitting layer and output to the substrate.

21. The display apparatus of claim 20, further comprising a bank in the non-light emission area,
wherein the total output amount of light emitted from the light emitting layer and output to the substrate is provided to satisfy
$${η}_{total} = A {\int }_{0}^{{sin}^{- 1} ( \frac{{n}_{b}}{{n}_{OLED} \cdot \sqrt{1 + {( \frac{h}{v} )}^{2}}} )} {I}_{OLED} ( θ ) d θ + B ,$$
where ηₜₒₜₐₗ is the total output amount of light emitted from the light emitting layer and output to the substrate, A is a light conversion constant, n_{OLED} is a refractive index of the light emitting layer, n_{b} is a refractive index of the bank, V is a vertical length from an upper surface of the light emitting layer to a point at which the bank ends, h is a horizontal length from an end of the light emission area to the point at which the bank ends, I_{OLED}(θ) is an amount of light emitted from an inside of the light emitting layer, and B is a total output amount of light when there is no reflective portion.

22. The display apparatus of claim 21, wherein the plurality of subpixels include a pixel electrode below the light emitting layer, and
wherein I_{OLED}(θ) is provided to satisfy
$${I}_{OLED} ( θ ) = cos θ \cdot R ( θ ) ,$$
where cos θ is diffuse reflection, R(θ) is a degree of reflection, and θ is an incident angle of light incident on the pixel electrode after being emitted from the light emitting layer.

23. The display apparatus of claim 20, wherein the total output amount of light emitted from the light emitting layer and output to the substrate includes direct light directly output to the substrate after being emitted from the light emitting layer and reflective light reflected by the reflective portion and indirectly output to the substrate.

24. The display apparatus of claim 20, wherein the plurality of subpixels include a reflective electrode on the light emitting layer, and
wherein the depth of the reflective portion is a vertical length from an extension line of a lower surface of the reflective electrode to a point at which a bank ends in the non-light emission area.
